(19) United States
(12) Patent Application Publication
(10) Pub. No.: US 2006/0016472 A1
(43) Pub. Date: Jan. 26, 2006

(54) Electrolyte composition and solar cell using the same

(76) Inventors: Joung-Won Park, Suwon-si (KR); Ji-Won Lee, Suwon-si (KR); Wha-Sup Lee, Suwon-si (KR); Kwang-Soon Ahn, Suwon-si (KR); Jae-Man Choi, Suwon-si (KR); Byong-Cheol Shin, Suwon-si (KR)

Correspondence Address: MCGUIREWOODS, LLP, 1750 TYSONS BLVD, SUITE 1800, MCLEAN, VA, 22102, US

(21) Appl. No.: 11/166,148

(22) Filed: Jun. 27, 2005

(30) Foreign Application Priority Data
Jun. 26, 2004 (KR) 10-2004-0048658

(51) Int. Cl. H01G 9/02; H01L 31/00

(52) U.S. Cl. 136/263; 252/62.2

(57) ABSTRACT

An electrolyte composition and a solar cell using the same are provided. The electrolyte composition comprises an electron donor compound “A” having a lone electron pair, an iodine salt. and iodine (I₂). The electrolyte composition according to the present invention increases electrons in a porous film to improve a charge integration capacity and increases the open circuit voltage, thereby providing a dye sensitized solar cell with high efficiency.

### CROSS REFERENCE TO RELATED APPLICATION

This application claims priority to and the benefit of Korean Patent Application No. 10-2004-0048658, filed on Jun. 26, 2004, in the Korean Intellectual Property Office, the disclosure of which is incorporated herein in its entirety by reference.

### BACKGROUND OF THE INVENTION

1. Field of the Invention

The present invention relates to an electrolyte composition and a solar cell using the same. In particular, the present invention relates to a dye sensitized solar cell that operates on electrochemical principles.

2. Description of the Related Art

A dye sensitized solar cell is an electrochemical solar cell that uses an oxide semiconductor electrode. The oxide semiconductor electrode comprises photosensitive dye molecules for absorbing visible rays to generate electron-hole pairs and titanium oxide for transferring the generated electrons.

Conventional silicon solar cells simultaneously perform a solar energy absorbing process and an electromotive force generating process by separating the electron-hole pair in a silicon semiconductor. In contrast, dye sensitized solar cells separately perform a solar energy absorbing process and a charge transfer process. The dye absorbs solar energy and the semiconductor transfers charges.

The dye sensitized solar cell has advantages of low manufacturing costs and an environment-friendly manufacturing process, but is limited in application due to its low energy conversion efficiency.

In the solar cell, the energy conversion efficiency, which is the photoelectric transformation efficiency, is proportional to the amount of electrons that are generated by the absorption of sunlight. To increase the photoelectric transformation efficiency, the amount of the absorbed sunlight may be increased or the amount of the absorbed dye may be increased. This increases the amount of electrons that are generated and prevents the excited electrons that are generated from being annihilated due to an electron-hole recombination.

To increase the amount of the absorbed dye per unit area, a method for manufacturing nano-sized particles of a semiconductor oxide has been developed. To increase the absorption of sunlight, a method for increasing the reflective ratio of a platinum electrode or mixing a semiconductor oxide having a few micron size has been developed.

Korean Published Patent No. 10-2003-0065957 discloses a dye sensitized solar cell that has a gel type polymer electrolyte that contains polyvinylidene fluoride. In this patent, the volatility of an electrolyte solvent is reduced, thereby increasing the photoelectric transformation efficiency within certain limits. Efforts to increase the amount of redox electrons is by changing a property of the electrolyte have proven insufficient. Thus, a new method for improving the photoelectric conversion efficiency is needed. Such improvements would also improve the open circuit voltage (V_{oc}) of the solar cell.

### SUMMARY OF THE INVENTION

The present invention provides an electrolyte composition in which a compound is added to improve the open circuit voltage and increase the efficiency of a dye sensitized solar cell.

The present invention also provides a solar cell that uses the electrolyte.

Additional features of the invention will be set forth in the description which follows, and in part will be apparent from the description, or may be learned by practice of the invention.

The present invention discloses an electrolyte composition of a solar cell comprising an electron donor compound “A” having a lone electron pair, an iodine salt, and iodine (I₂).

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention.

FIG. 1 illustrates an operation principle of a general dye sensitized solar cell.

FIG. 2 is a schematic sectional view of a dye sensitized solar cell according to an exemplary embodiment of the present invention.

FIG. 3 illustrates an effect and a reaction of a compound “A” in a dye sensitized solar cell according to an exemplary embodiment of the present invention.

FIG. 4 and FIG. 5 are graphs illustrating current-voltage characteristics where line (a) indicates a conventional dye sensitized solar cell, line (b) indicates a dye sensitized solar cell according to a first embodiment of the present invention, and line (c) indicates a dye sensitized solar cell according to a second embodiment of the present invention.

FIG. 6 is a schematic view illustrating a result of a rising voltage when a compound “A” is added according to the present invention.

### DETAILED DESCRIPTION OF THE INVENTION

According to the present invention, the electron donor compound “A” comprised in the electrolyte is absorbed to the porous film to increase the electrons in the porous film, thereby improving charge integration. Accordingly, the open circuit voltage can be increased to fabricate a dye sensitized solar cell with the high efficiency.

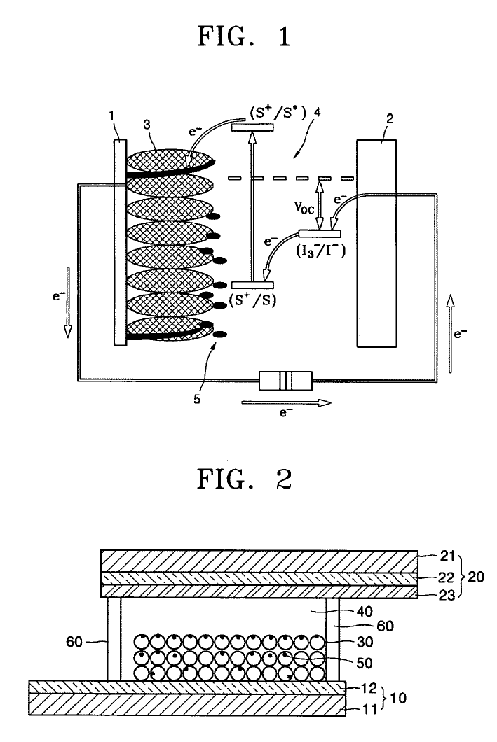

FIG. 1 illustrates the operation of a typical dye sensitized solar cell. When sunlight is absorbed by a dye molecule 5, the dye molecule 5 transitions from a ground state to an excited state to provide an electron-hole pair. Excited electrons are injected into a conduction band in a grain boundary of a porous film 3. The injected electrons are transferred to a first electrode 1 and are then transferred to a second electrode 2 through an external circuit. The dye molecule that is oxidized is reduced by an iodide ion (I⁻) in an electrolyte 4. An oxidized trivalent iodide ion (I₃⁻) performs a reduction reaction with the electron, which reaches the second electrode 2, for charge neutrality. The dye sensitized solar cell utilizes a grain boundary reaction unlike a conventional p-n junction silicon solar cell.

FIG. 2 is a schematic sectional view illustrating a dye sensitized solar cell according to an exemplary embodiment of the present invention.

The dye sensitized solar cell has a sandwich structure with a plate-shaped first electrode 10 and a plate-shaped second electrode 20 facing each other. A nano-grain sized porous film 30 is coated on one surface of the first electrode 10. A photo-sensitive dye 50 with electrons that are excited by an absorbed visible ray is absorbed to a surface of the nano-grain sized porous film 30. The first electrode 10 and the second electrode 20 are coupled with a support 60. A redox electrolyte 40 fills a space between the first electrode 10 and the second electrode 20 and is uniformly dispersed in the porous film 30. In FIG. 2, the electrolyte 40 is positioned between the porous film 30 and the second electrode 20 for convenience. However, this is not intended to limit the scope of the present invention.

The electrolyte 40 receives the electrons from a counter electrode through a redox reaction of the iodide ions (I⁻/I₃⁻), and transfers the electrons to the dye. The open circuit voltage is based on a difference between a Fermi energy level of the porous film 30 and the redox level of the electrolyte 40.

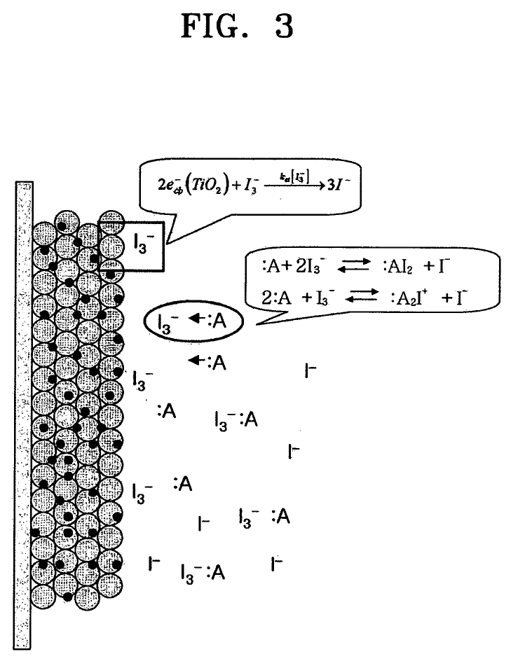

FIG. 3 illustrates an effect and a reaction of a compound “A” in the dye sensitized solar cell according to an exemplary embodiment of the present invention. In the general dye sensitized solar cell, electrons of a TiO₂ film take part in chemical Equation 1 to be reduced in a TiO₂ conduction band, thereby allowing a low open circuit voltage (V_{oc}). In the reaction of the electrolyte and the dye, the trivalent iodide ion (I₃⁻) is generally reduced according to the following chemical Reaction 1:

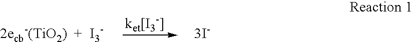

The present invention relates to a dye sensitized solar cell that operates on electrochemical principles. The electron donor compound “A” that has a lone electron pair and is contained in the electrolyte reacts with the trivalent iodide ion (I₃⁻) of the electrolyte to increase the concentration of the iodide ion (I⁻), thereby decreasing the reaction between the electron of TiO₂ film with the trivalent iodide ion (I₃⁻). Accordingly, the electrons are increased in the TiO₂ film. Thus, the electrons of the conduction band of the TiO₂ film are increased, thereby improving the open circuit voltage (V_{oc}). When the electron donor compound “A” having the lone electron pair is added, the reaction occurs as in chemical Reaction 2:
:A+2I₃⁻ [symbol] :AI₂+I⁻
2:A+I₃⁻ [symbol] :A₂I⁺+I⁻ Reaction 2

According to an exemplary embodiment of the present invention, the electron donor compound “A” of the present invention may have a total concentration of 30 to 1,000 parts by weight per 100 parts by weight of iodine (I₂). If the total concentration is less than 30 parts by weight, the reaction does not progress smoothly. If the total concentration is more than 1,000 parts by weight, the voltage increases, but the current decreases, thereby undesirably reducing efficiency.

The electron donor compound “A” having the lone electron pair according to the present invention may be a hetero compound that has at least one atom including, but not limited to nitrogen, phosphorous, and sulphur.

The electron donor compound “A” may include aliphatic amines that have 1-20 carbons, aryl amines that have 1-20 carbons, and heterocyclic amines that have 1-20 carbons. The electron donor compound “A” may include, but is not limited to pyridine, pyridazine, pyrimidine, pyrazine, triazine, triazole, thiazole, thiadiazol, 4-tert-butylpyridine, 2-amino-pyrimidine, and derivatives thereof.

The electron donor compound “A” may include aliphatic sulfur compounds that have 1-20 carbons, aryl sulfur compounds that have 1-20 carbons, and heterocyclic sulfur compounds that have 1-20 carbons. The electron donor compound “A” may include, but is not limited to dimethyl sulfide, methyl phenyl sulfide, and thiophene.

The electron donor compound “A” may include, but is not limited to an aliphatic phosphorous compound that has 1-20 carbons, an aryl phosphorous compound that has 1-20 carbons, and a heterocyclic phosphorous compound that has 1-20 carbons.

As shown in Reaction 2, the electron donor compound “A” decreases the concentration of the trivalent iodide ion (I₃⁻) and decreases the reaction of the electron of the TiO₂ film with the trivalent iodide ion (I₃⁻). Accordingly, the concentration of electrons in the conduction band of the TiO₂ film increases, thereby increasing the open circuit voltage (V_{oc}). Further, since the reduction reaction of the trivalent iodide ion (I₃⁻) is increased, the open circuit voltage (V_{oc}) is increased according to the following Equation:

$${V}_{∝} = ( \frac{kT}{e} ) ln ( \frac{{I}_{inj}}{{n}_{cb} {k}_{et} [ {I}_{3}^{-} ]} )$$

In the electrolyte, the ions I⁻ and I₃⁻ may be generated from iodine salt. The ions I⁻ and I₃⁻ coexist and cause a reversible reaction. The ions I⁻ and I₃⁻ may be generated from lithium iodide, natrium iodide, kalium iodide, magnesium iodide, copper iodide, silicon iodide, manganese iodide, barium iodide, molybdenum iodide, calcium iodide, iron iodide, cesium iodide, zinc iodide, mercury iodide, ammonium iodide, methyl iodide, methylene iodide, ethyl iodide, ethylene iodide, isopropyl iodide, isobutyl iodide, benzyl iodide, benzoyl iodide, allyl iodide, and imidazolium iodide. But, these examples are not intended to limit the scope of the present invention.

The iodine salt may have a concentration of 150 to 3,000 parts by weight per 100 parts by weight of iodine (I₂). If the concentration of the iodine salt is less than 150 parts by weight, the reaction does not progress smoothly. If the concentration of the iodine salt is greater than 3,000 parts by weight, the electron flow is undesirably prevented, thereby decreasing the current value.

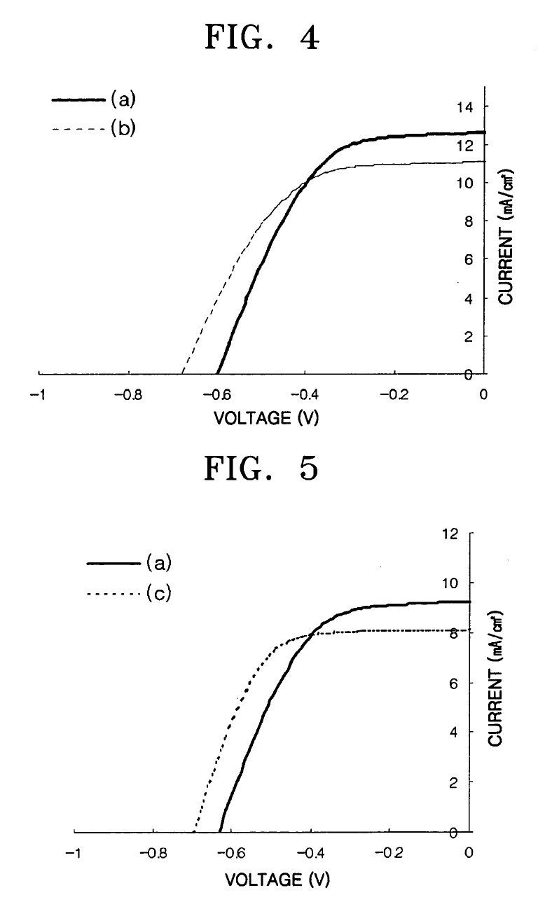

Line (b) of FIG. 4 indicates the open circuit voltage which increases when 2-aminopyrimidine is added according to an exemplary embodiment of the present invention. Line (c) of FIG. 5 indicates the open circuit voltage which increases when 4-tert-butylpyrimidine is added according to an exemplary embodiment of the present invention.

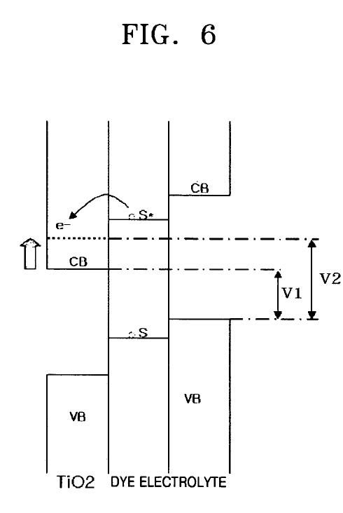

In FIG. 6, when the electron donor compound “A” is added, the electrons of the conduction band increase, thereby increasing the open circuit voltage (V_{oc}).

The inventive electrolyte composition may further comprise an organic solvent. The organic solvent may include, but is not limited to acetonitrile, ethylene glycol, butanol, isobutyl alcohol, isopentyl alcohol, isopropyl alcohol, ethyl ether, dioxane, tetrahydrobutane, tetrahydrofuran, n-butyl ether, propyl ether, isopropyl ether, acetone, methyl ethyl ketone, methyl butyl ketone, methyl isobutyl ketone, ethylene carbonate, diethyl carbonate, propylene carbonate, dimethyl carbonate, ethyl methyl carbonate, gamma-butyrolactone, N-methyl-2-pyrolidone, and 3-Methoxypropionitrile. The concentration of the organic solvent may comprise 10 wt % to 90 wt % of the total electrolyte composition. Further, the organic solvent may not be required. For example, materials such as imidazolium-based iodine do not necessarily need a solvent since they exist in a liquid state.

Further, the inventive solar cell includes the first electrode and second electrode facing each other, a porous film that is interposed between the first electrode and the second electrode and has the absorbed dye, and the electrolyte composition that is interposed between the first electrode and second electrode and has the electron donor compound “A” containing the lone electron pair, the iodine salt, and the iodine (I₂).

The first electrode 10 may comprise a transparent plastic substrate or a glass substrate 11 comprising polyethylene terephthalate, polyethylene naphthalate, PC, polypropylene, PI, and triacetyl cellulose, for example. The first electrode 10 may also comprise a conductive film 12 comprising at least one of indium tin oxide (ITO), indium oxide, tin oxide, zinc oxide, sulfur oxide, fluorine oxide and a combination thereof that is coated on the transparent plastic substrate or the glass substrate 11.

The porous film 30 has nano-grains, which are uniformly dispersed and have nanometer-sized grain diameters. The porous film 30 has a suitable surface roughness while maintaining porosity. Conductive particles such as ITO may also be added to the porous film 30 to facilitate the electron transfer. Light scattering particles may also be added to the porous film 30 to extend the light path, thereby improving the efficiency.

An absorbable dye comprises materials such as a ruthenium composite to absorb visible rays. Ruthenium belongs to a class of platinum metals and may be used in many organic metal composite compounds. In addition, a metal composite comprising aluminum, platinum, palladium, europium, lead or iridium, and the like may be used. A general dye may be N3dye[cis-bis(isothiocyanato)bis(2,2′-bipyridyl-4,4′-dicarboxylato)-ruthenium(II)], N719dye[cis-bis(isothiocyanato)bis(2,2′-bipyridyl-4,4′-dicarboxylato)-ruthenium(II)-bis tetrabutylammonium]), or the like.

Further, various colored organic pigments may be used due to their low price and abundance, and are undergoing vigorous development. For example, “Coumarin,” “Pheophorbide a,” a kind of Porphyrin, and the like may be used alone or may be mixed and used with the ruthenium composite to improve the absorption of the long-wavelength visible ray, thereby improving the efficiency.

Such a dye is naturally absorbed 12 hours after the porous film is immersed in an alcoholic solution with the dye solved.

The second electrode 20 may comprise a transparent plastic substrate or a glass substrate 21 including, but not limited to polyethylene terephthalate, polyethylene naphthalate, PC, polypropylene, PI, and triacetyl cellulose. The second electrode may further comprise a first conductive film 22 coated on the transparent plastic substrate or the glass substrate 21, and a second conductive film 23 comprising platinum or another precious metal that is coated on the first conductive film 22. Platinum is preferred due to its excellent reflectivity.

The first electrode 10 and second electrode 20 are coupled together by the support 60 of an adhesive film or a thermoplastic polymer film such as Surlyn®, which seals their interior. Then, minute through-holes are provided at the first electrode 10 and the second electrode 20 so that the electrolyte can be injected into the space between the two electrodes through the minute through-holes. Next, the holes are covered and sealed by an adhesive.

In addition to the support 60, the adhesive such as an epoxy resin or an ultraviolet ray (UV) curing agent may be used to couple and seal the first electrode 10 and second electrode 20. At this time, a curing process may be also performed after a heat treatment or a UV treatment.

A manufacture process of the dye sensitized solar cell of the present invention is described as follows. The first electrode 10 and second electrode 20 formed of the transparent material are prepared, and the porous film 30 is formed on one surface of the first electrode 10. Then, the dye is absorbed into the porous film 30 and the second electrode 20 is disposed to face the porous film 30 of the first electrode 10. Next, the space between the porous film 30 and the second electrode 20 is filled with the electrolyte composition 40, which comprises the electron donor compound “A” with the lone electron pair, the iodine salt, and iodine (I₂), and is then sealed.

Thus, the present invention will be described in greater detail with reference to the following examples. The following examples are for illustrative purposes only and are not intended to limit the scope of the invention.

### Embodiment 1

A titanium-oxide particle dispersion with a particle diameter of about 5 nm to 15 nm was coated using a doctor blade method on an 1 cm² area of a conductive film 12. This was then thermally sintered for 30 minutes at a temperature of 450° C. to form the porous film 30 having a thickness of 10 μm. The conductive film 12 of the first electrode 10 is comprised of ITO.

Next, after a sample was maintained at a temperature of 80° C., it was immersed in a 0.3 mM Ru(4,4′-dicarboxy-2,2′-bipyridine)₂(NCS)₂ dye pigment liquid, which is prepared using ethanol. Next, the dye absorption process was performed for 12 hours. Then, the dye-absorbed porous film 30 was rinsed using ethanol and was dried at a room temperature.

For the second electrode 20, the second conductive film 23 formed of platinum was sputtered on a first conductive film 22 and the minute through-holes were drilled with a diameter of 0.75 mm to inject the electrolyte 16. The first conductive film 22 was formed of ITO.

The support 60 was interposed between the first electrode 10 and the second electrode 20. The support 60 is formed of a 60 μm thermal plastic polymer film. Then, the first electrode 10 and second electrode 20 were pressed for 9 seconds at a temperature of 100° C. to couple them together.

Additionally, the redox electrolyte 40 is injected through the minute through-hole of the second electrode 20, and the minute through-hole is covered using a glass and a thermal plastic polymer film to complete the dye sensitized solar cell. The redox electrolyte 40 comprised 1500 g of 1,2-dimethyl-3-hexylimidazolium iodide, 375 g of 2-aminopyrimidine, 104 g of lithium iodide (LiI), and 100 g of I₂ in an acetonitrile solvent.

A xenon lamp (Oriel, 91193) was used as the light source for measuring the efficiency, the open circuit voltage, short circuit current, current density and the like of the dye sensitized solar cell. The sunlight condition of the xenon lamp was corrected using a standard solar cell.

A current-voltage curve is plotted using a light source with an intensity of 100 mW/cm² and a silicon standard cell. Line (b) of FIG. 4 illustrates the current-voltage curve of the solar cell manufactured according to Embodiment 1, and indicates an efficiency of 4.11%, an open circuit voltage of 0.677 V, a short circuit current of 11.070 mA/cm², and a density of 55%.

### Embodiment 2

Embodiment 2 was prepared in the same manner as in Embodiment 1 except that 1489 g of 1,2-dimethyl-3-hexylimidazolium iodide, 533 g of 4-tert-butylpyridine, 111 g of LiI, and 80 g of I₂ were dissolved in an acetonitrile solvent and used as the redox electrolyte 40.

Line (c) of FIG. 5 illustrates the current-voltage curve of the dye sensitized solar cell manufactured according to Embodiment 2, and indicates an efficiency of 3.59%, an open circuit voltage of 0.698 V, the short circuit current of 8.11 mA/cm², and a density of 63%.

### COMPARATIVE EXAMPLE 1

Comparative Example 1 was prepared in the same manner as in Embodiment 1 except that 1500 g of 1,2-dimethyl-3-hexylimidazolium iodide, 100 g of LiI and 100 g of I₂ were dissolved in an acetonitrile solvent and used as redox electrolyte 40.

Line (a) of FIG. 4 illustrates the current-voltage curve of the dye sensitized solar cell prepared according to the Comparative 1, and indicates a efficiency of 3.60%, an open circuit voltage of 0.614 V, a short circuit current of 12.52 mA/cm², and a density of 48%.

### COMPARATIVE EXAMPLE 2

Comparative Example 2 was prepared in the same manner as in Embodiment 1 except that 1489 g of 1,2-dimethyl-3-hexylimidazolium iodide, 111 g of LiI, and 80 g of I₂ were dissolved in an acetonitrile solvent and used as the redox electrolyte 40.

Line (d) of FIG. 5 illustrates the current-voltage curve of the dye sensitized solar cell manufactured according to Comparative Example 2, and indicates an efficiency of 3.15%, an open circuit voltage of 0.627 V, the short circuit current of 9.19 mA/cm², and a density of 55%.

TABLE 1

| | | Open circuit | Short circuit | | | |
|---|---|---|---|---|---|---|
| | | voltage | current | | Efficiency | Efficiency |
| | Additive | (V_{oc}, V) | (mA/cm²) | Density | (%) | increase |
| Embodiment 1 | 2-amino-pyrimidine | 0.677 | 11.07 | 55 | 4.11 | 14.2% |
| Embodiment 2 | 4-tert-butylpyridine | 0.698 | 8.11 | 63 | 3.59 | 14.0% |
| Comparative | — | 0.614 | 12.52 | 48 | 3.60 | — |
| example 1 | | | | | | |
| Comparative | — | 0.627 | 9.19 | 55 | 3.15 | — |
| example 2 | | | | | | |

As shown in Table 1, when 2-amino-pyrimidine or 4-tert-butylpyridine comprising an element having a lone electron pair is added to the electrolyte according to Embodiments 1 and 2, a high open circuit voltage and an improved density and efficiency are obtained in comparison to the comparative example using only the general electrolyte. Specifically, the open circuit voltage of the solar cell was increased by 10% to 40% on the basis of the general electrolyte composition without the electron donor compound “A” added.

It will be apparent to those skilled in the art that various modifications and variation can be made in the present invention without departing from the spirit or scope of the invention. Thus, it is intended that the present invention cover the modifications and variations of this invention provided they come within the scope of the appended claims and their equivalents.

What is claimed is:

1. An electrolyte composition of a solar cell, comprising:
an electron donor compound having a lone electron pair;
an iodine salt; and
iodine (I₂).

2. The composition of claim 1,
wherein the concentration of the electron donor compound is 30 to 1,000 parts by weight per 100 parts by weight of iodine (I₂).

3. The composition of claim 1,
wherein the electron donor compound is selected from the group consisting of an aliphatic amine having a 1 to 20 carbons, an aryl amine having 1 to 20 carbons, and a heterocyclic amine having 1 to 20 carbons.

4. The composition of claim 1,
wherein the electron donor compound is selected from the group consisting of a heterocyclic amine having 1 to 20 carbons.

5. The composition of claim 4,
wherein the electron donor compound is selected from the group consisting of pyridine, pyridazine, pyrimidine, pyrazine, triazine, triazole, thiazole, thiadiazol, 4-tert-butylpyridine, 2-amino-pyrimidine, and derivatives thereof.

6. The composition of claim 1,
wherein the electron donor compound is selected from the group consisting of an aliphatic sulfur compound having 1 to 20 carbons, an aryl sulfur compound having 1 to 20 carbons, and a heterocyclic sulfur compound having 1 to 20 carbons.

7. The composition of claim 6,
wherein the electron donor compound is selected from the group consisting of dimethyl sulfide, methyl phenyl sulfide, thiophene and derivatives thereof.

8. The composition of claim 1,
wherein the electron donor compound is selected from the group consisting of an aliphatic phosphorous compound having 1 to 20 carbons, an aryl phosphorous compound having 1 to 20 carbons, and a heterocyclic phosphorous compound having 1 to 20 carbons.

9. The composition of claim 1,
wherein the iodine salt is selected from the group consisting of lithium iodide, natrium iodide, kalium iodide, magnesium iodide, copper iodide, silicon iodide, manganese iodide, barium iodide, molybdenum iodide, calcium iodide, iron iodide, cesium iodide, zinc iodide, mercury iodide, ammonium iodide, methyl iodide, methylene iodide, ethyl iodide, ethylene iodide, isopropyl iodide, isobutyl iodide, benzyl iodide, benzoyl iodide, allyl iodide, and imidazolium iodide.

10. The composition of claim 9,
wherein the concentration of the iodine salt is about 150 to 3,000 parts by weight per 100 parts by weight of iodine (I₂).

11. The composition of claim 1, further comprising an organic solvent,
wherein the organic solvent is one or more compounds selected from the group consisting of acetonitrile, ethylene glycol, butanol, isobutyl alcohol, isopentyl alcohol, isopropyl alcohol, ethyl ether, dioxane, tetrahydrobutane, tetrahydrofuran, n-butyl ether, propyl ether, isopropyl ether, acetone, methyl ethyl ketone, methyl butyl ketone, methyl isobutyl ketone, ethylene carbonate, diethyl carbonate, propylene carbonate, dimethyl carbonate, ethyl methyl carbonate, gamma-butyrolactone, N-methyl-2-pyrolidone, and 3-methoxypropionitrile, and
wherein the solvent has a concentration of 10 wt % to 90 wt % of the total amount of the composition.

12. A solar cell, comprising:
a first electrode and a second electrode facing each other;
a porous film interposed between the first electrode and second electrode and comprising an absorbed dye; and
an electrolyte composition of claim 1, interposed between the first electrode and second electrode.
